(19) United States
(12) Patent Application Publication
(10) Pub. No.: US 2013/0279285 A1
(43) Pub. Date: Oct. 24, 2013

(54) SEMICONDUCTOR MEMORY DEVICE

(71) Applicant: SAMSUNG ELECTRONICS CO., LTD., Suwon-si (KR)

(72) Inventors: Han Sik Yoo, Seoul (KR); Bum Jae Lee, Hwaseong-si (KR)

(73) Assignee: SAMSUNG ELECTRONICS CO., LTD., Suwon-si (KR)

(21) Appl. No.: 13/767,429

(22) Filed: Feb. 14, 2013

(30) Foreign Application Priority Data
Apr. 19, 2012 (KR) 10-2012-0041155

(51) Int. Cl. G11C 8/08

(52) U.S. Cl. CPC G11C 8/08
USPC 365/230.06

(57) ABSTRACT

A semiconductor memory device includes a memory cell array region and a column decoder. The memory cell array region includes a plurality of memory cell arrays that are arranged in row and column directions. The column decoder includes a first column select line (CSL) driver and a second CSL driver that are disposed adjacent to a first edge of the memory cell array region extending in the row direction and that have different physical layouts.

### CROSS-REFERENCE TO RELATED APPLICATIONS

This application claims the benefit of Korean Patent Application No. 10-2012-0041155, filed on Apr. 19, 2012, in the Korean Intellectual Property Office, the disclosure of which is incorporated herein in its entirety by reference.

### BACKGROUND

Example embodiments relate to a semiconductor memory device, and more particularly, to a semiconductor memory device having a protrusion portion at an edge of a memory cell array region.

A memory cell array region includes a plurality of memory cell arrays, and generally has a rectangular edge. In order to select a memory cell in the memory cell array region, in correspondence to an address, a row decoder and a column decoder are disposed adjacent to the memory cell array region. However, when the memory cell array region does not have the rectangular edge but protrudes toward the row decoder or the column decoder, the row decoder or the column decoder has to be disposed apart from the memory cell array region by a protruded distance, such that a total of a chip area is increased and thus an inefficiency occurs.

### SUMMARY

The present disclosure provides a semiconductor memory device including a memory cell array region.

According to one embodiment, there is provided a semiconductor memory device including a memory cell array region, protrusion conjunction regions, and a column decoder. The memory cell array region may include a plurality of memory cell arrays each array including memory cells that are arranged in row and column directions, sub-wordline drivers that are disposed between memory cell arrays in the row direction, and conjunction regions that are disposed between sub-wordline drivers in the column direction. The protrusion conjunction regions are disposed adjacent to a first group of the sub-wordline drivers positioned at a first edge of the memory cell array region extending in the row direction and protrude from the first edge in the column direction. The column decoder may include first column select line (CSL) drivers each having a first physical layout and second CSL drivers each having a second physical layout different from the first physical layout, the first and second CSL drivers being disposed adjacent to the first edge of the memory cell array region. The number of the first CSL drivers may be greater than the number of the second CSL drivers.

According to another embodiment, there is provided a semiconductor memory device including a memory cell array region, a protrusion portion, sub-wordline drivers, a row decoder, and a column decoder. The memory cell array region may include a plurality of memory cell arrays arranged in row and column directions. The protrusion portion may protrude from at least one edge of the memory cell array region in at least one of the row and column directions. The sub-wordline drivers may be disposed between memory cell arrays in the row direction, and may be configured to generate word line signals in response to driver signals. The row decoder including first drivers and second drivers, may be disposed adjacent to a first edge of the memory cell array region extending in the column direction, and may be configured to generate the driver signals. The column decoder including third drivers and fourth drivers, may be disposed adjacent to a second edge of the memory cell array region extending in the row direction, and may be configured to generate column selection line (CSL) signals. At least one of the first drivers may include a physical layout different from at least one of the second drivers, or at least one of the third drivers may include a physical layout different from at least one of the fourth drivers.

According to another embodiment, there is provided a semiconductor memory device including a memory cell array region, a column decoder, and a row decoder. The memory cell array region may include a plurality of memory cell arrays arranged in row and column directions. The column decoder may include a plurality of column selection line (CSL) drivers disposed adjacent to a first edge of the memory cell array region, and may be configured to generate a plurality of column selection line signals. The row decoder may include a plurality of main word line (MWL) drivers disposed adjacent to a second edge of the memory cell array region, and may be configured to generate a plurality of main word line signals. The CSL drivers may include first and second CSL drivers, each of the first CSL drivers including a physical layout different from each of the second CSL drivers. The number of the first CSL drivers may be greater than a number of the second CSL drivers.

### BRIEF DESCRIPTION OF THE DRAWINGS

Exemplary embodiments will be more clearly understood from the following detailed description taken in conjunction with the accompanying drawings in which:

FIG. 1 is a schematic layout of a semiconductor memory device according to an embodiment;

FIG. 2 is a partially magnified view of a layout of the semiconductor memory device of FIG. 1 according to an embodiment;

FIG. 3 is a partially magnified view of a layout of the semiconductor memory device of FIG. 1 according to another embodiment;

FIG. 4 is a partially magnified view of a layout of the semiconductor memory device of FIG. 1 according to another embodiment;

FIG. 5A is a partially magnified view of a memory cell array region of FIGS. 2 and 4, and a column decoder according to an embodiment;

FIG. 5B is a partially magnified view of a memory cell array region of FIGS. 2 and 4, and a column decoder according to another embodiment;

FIG. 6 is a partially magnified view of a memory cell array region of FIGS. 3 and 4, and a row decoder, according to an embodiment;

FIG. 7 illustrates layouts of first and second drivers of FIGS. 5A and 6, according to an embodiment;

FIG. 8 illustrates layouts of first and second drivers of FIGS. 5A and 6, according to another embodiment;

FIG. 9 illustrates layouts of first and second drivers of FIGS. 5A and 6, according to another embodiment;

FIG. 10 illustrates layouts of first and second drivers of FIGS. 5A and 6, according to another embodiment;

FIG. 11 illustrates layouts of first and second drivers of FIGS. 5A and 6, according to another embodiment;

FIG. 12 schematically illustrates a structure of transistors shown in FIGS. 7 through 11 according to an embodiment;

FIG. 13 is a circuit diagram of drivers shown in FIGS. 7 through 11, according to an embodiment;

FIG. 14 illustrates a layout diagram of a first column select line (CSL) driver in the circuit diagram of FIG. 13, according to an embodiment;

FIG. 15 illustrates a layout diagram of a second CSL driver in the circuit diagram of FIG. 13, which is a layout diagram of a second driver DRVb1 of FIG. 7 according to an embodiment;

FIG. 16 illustrates a layout diagram of a second CSL driver in the circuit diagram of FIG. 13, which is a layout diagram of a second driver DRVb2 of FIG. 8 according to an embodiment; and

FIG. 17 illustrates an exemplary layout diagram of a second CSL driver in the circuit diagram of FIG. 13, which is a layout diagram of a second driver DRVb5 of FIG. 11.

### DETAILED DESCRIPTION OF THE EMBODIMENTS

The present disclosure will now be described more fully with reference to the accompanying drawings, in which exemplary embodiments are shown. The disclosure may, however, be embodied in many different forms, and should not be construed as being limited to the embodiments set forth herein. Thus, the disclosure may include all revisions, equivalents, or substitutions which are included in the concept and the technical scope related to the disclosure.

Like reference numerals in the drawings denote like elements. In the drawings, the dimension of structures may be exaggerated for clarity.

Furthermore, all examples and conditional language recited herein are to be construed as being without limitation to such specifically recited examples and conditions. Throughout the specification, a singular form may include plural forms, unless there is a particular description contrary thereto. Also, terms such as “comprise,” “include,” “including,” or “comprising” is used to specify existence of a recited form, a number, a process, an operation, a component, and/or groups thereof, not excluding the existence of one or more other recited forms, one or more other numbers, one or more other processes, one or more other operations, one or more other components and/or groups thereof. As used herein, the term “and/or” includes any and all combinations of one or more of the associated listed items. Throughout the specification, while terms “first” and “second” are used to describe various components, the components are not necessarily limited to the terms “first” and “second”. Unless indicated otherwise, the terms “first” and “second” are used only as a naming convention to distinguish between each component. As used herein, it will also be understood that when a first feature is referred to as being “connected to”, “combined with”, “on,” or “interfaced with” a second feature, intervening third features may also be present.

Unless expressly described otherwise, all terms including descriptive or technical terms which are used herein should be construed as having meanings that are known to one of ordinary skill in the art. Also, terms that are defined in a general dictionary and that are used in the following description should be construed as having meanings that are equivalent to meanings used in the related description, and unless expressly described otherwise herein, the terms should not be construed as being ideal or excessively formal.

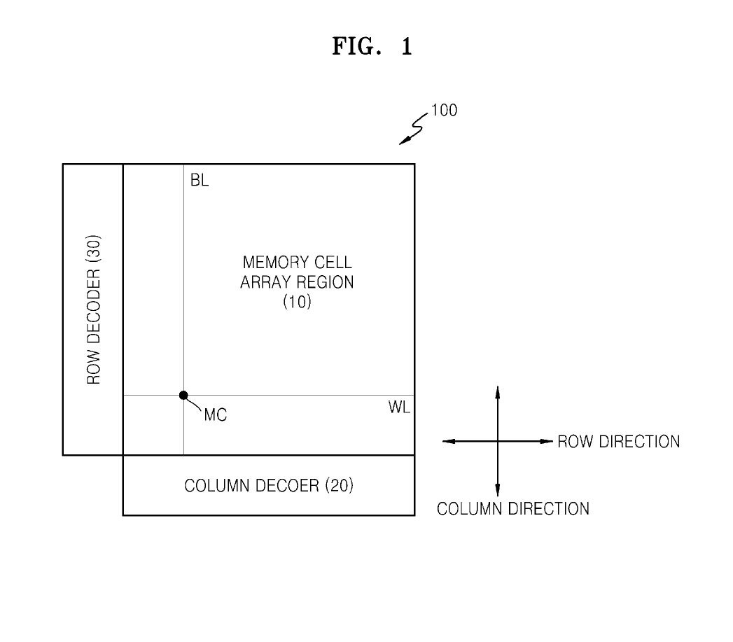

FIG. 1 is a schematic layout of a semiconductor memory device 100 according to an embodiment.

Referring to FIG. 1, the semiconductor memory device 100 includes a memory cell array region 10, a column decoder 20, and a row decoder 30. The memory cell array region 10 includes a plurality of memory cells MC that may be accessed by a wordline WL and a bitline BL. Each memory cell MC may be a volatile memory cell or a non-volatile memory cell. For example, each memory cell MC may include a dynamic random access memory (DRAM) cell, a flash memory cell, a magnetoresistive random access memory (MRAM) cell, a phase-change random access memory (PRAM) cell, or the like and is not limited thereto.

The column decoder 20 may receive a column address and may select a bitline BL that corresponds to the column address. The row decoder 30 may receive a row address and may select a wordline WL that corresponds to the row address. A memory cell MC from among the memory cells MC which is connected to the selected bitline BL and wordline WL may be activated, and data may be written to or read from the memory cell MC.

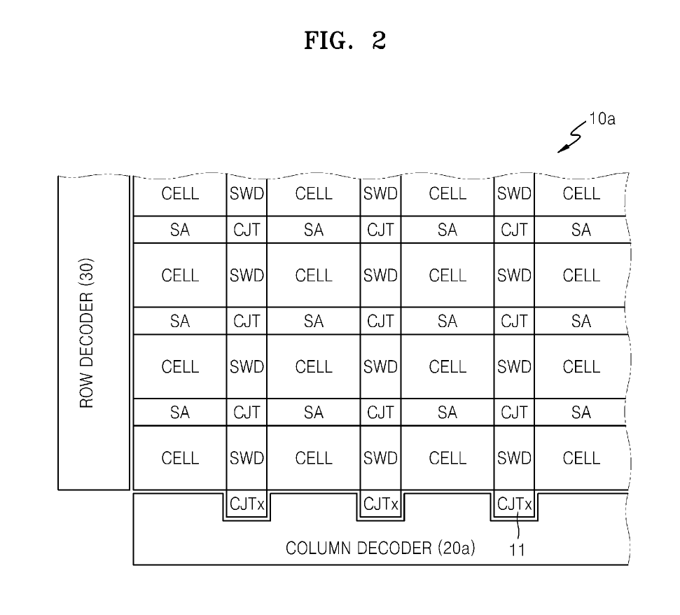

FIGS. 2 through 4 are partially magnified views of layouts of the semiconductor memory device 100 of FIG. 1 according to embodiments.

Referring to FIGS. 2 through 4, memory cell array regions 10a, 10b, and 10c include memory cell arrays CELL that are arranged in row and column directions. The memory cell arrays CELL include the memory cells MC that are arranged in the row and column directions, and hereinafter, it is assumed that the memory cells MC are arranged in a matrix of x rows in the row direction and y columns in the column direction. The memory cell arrays CELL may include wordlines WL that extend in the row direction, and the number of wordlines WL in each memory cell array CELL may be n. Also, the memory cell arrays CELL may include bitlines BL that extend in the column direction, and the number of bitlines BL in each memory cell array CELL may be m. The numbers n and m may be integers greater than 1. When the memory cell arrays CELL have an open bitline structure, m/2 bitlines BL and m/2 complementary bitlines BLB may exist in each memory cell array CELL.

The memory cell array regions 10a, 10b, and 10c may include sense amplifiers SA that are disposed between memory cell arrays CELL in the column direction. The sense amplifiers SA may be connected to the bitlines BL and the complementary bitlines BLB and thus may sense and amplify a value recorded to an activated memory cell MC. The value sensed by one of the sense amplifiers SA may be transferred to a local input/output (IO) line (not shown) and then may be output to an external source, in response to a column select line signal (hereinafter, referred to as ‘CSL signal’). For example, in a case where the open bitline structure is used, m/2 sense amplifiers SA may exist between memory cell arrays CELL, and each sense amplifier SA may be connected to a bitline BL in a memory cell array CELL of the memory cell arrays CELL which is disposed above and may be connected to a complementary bitline BLB in a memory cell array CELL of the memory cell arrays CELL which is disposed below.

In one embodiment, the column decoder 20 may include CSL drivers so as to provide CSL signals. Each of the CSL signals may control connection between the bitline BL and the local IO line. The number of CSLs may be equal to the number of bitlines BL. Thus, in one embodiment, m CSL drivers are used to control memory cells MC in each memory cell array CELL. Also, referring to FIG. 1, the CSL signal is delivered to sense amplifiers SA disposed away from the column decoder 20, e.g., in an upper portion in the memory cell array region 10, and thus, in one embodiment, the CSL drivers have considerably great current driving capacity. Also, for reliability, in one embodiment, the CSL drivers have the same electrical characteristics.

The memory cell array regions 10a, 10b, and 10c may include sub-wordline drivers SWD that are disposed between memory cell arrays CELL in the row direction. The row decoder 30 includes a wordline driver to drive a wordline WL that is commonly connected to memory cells MC that are arranged in the row direction in the memory cell array region 10. Because the wordline WL in the row direction in the memory cell array region 10 is considerably long, a wordline signal may attenuate. In order to prevent the attenuation of the wordline signal, the sub-wordline drivers SWD may be disposed between memory cell arrays CELL so as to newly reproduce and to re-transfer the wordline signal to the memory cell arrays CELL. For example, in one embodiment, n sub-wordline drivers SWD may be disposed in the memory cell array region 10, between memory cell arrays CELL. In one embodiment, a word line driver of the row decoder 30 may generate a main word line (MWL) signal and provide the MWL signal to sub-wordline drivers SWD.

The memory cell array regions 10a, 10b, and 10c may include conjunction regions CJT that are disposed between sub-wordline drivers SWD in the column direction and sense amplifiers SA in the row direction. Each conjunction region CJT may have a circuit so as to control operations of the sub-wordline drivers SWD that are disposed at both sides of the conjunction region CJT in the column direction. For example, each conjunction region CJT may have a control circuit so as to generate a signal (e.g., a PXID signal) to control a driving voltage (e.g., VPP) of the sub-wordline driver SWD. Also, each conjunction region CJT may have a circuit so as to control operations of the sense amplifiers SA that are disposed at both sides of the conjunction region CJT in the row direction. For example, each conjunction region CJT may have a control circuit (e.g., a LADRV) so as to provide a driving voltage to the sense amplifiers SA. In more detail, in one embodiment, each sense amplifier SA may include a p-channel metal-oxide-semiconductor (PMOS) sense amplifier that is driven by a power voltage VDD, and an n-channel MOS (NMOS) sense amplifier that is driven by a ground voltage VSS, and each conjunction region CJT may have a circuit to provide a power voltage VDD to the PMOS sense amplifier, and/or a circuit to provide a ground voltage VDD to the NMOS sense amplifier. U.S. Pat. No. 7,729,195, which is incorporated herein by reference in its entirety, discloses aspects of PXID signals and control circuits LADRV related to sub-wordline drivers SWD and sense amplifiers SA, respectively.

Referring to FIG. 2, the semiconductor memory device 100 may include the memory cell array region 10a and protrusion portions 11 that protrude from a first edge of the cell array region 10a, wherein a first group of the memory cell arrays CELL are disposed at the first edge of the memory cell array region 10a. As a result, the protrusion portions protrude toward a column decoder 20a. Each protrusion portion 11 may be substantially the same as each conjunction region CJT between sub-wordline drivers SWD, and hereinafter, may be referred to as ‘first protrusion conjunction region CJTx.’

The CSL drivers that are arranged in the row direction in the column decoder 20a generally have the same layout so as to ensure electrical characteristics that are equal to each other. However, because a width of the CSL drivers in the row direction is greater than a width of the sense amplifiers SA, not all m CSL drivers can be disposed between the protrusion portions 11. Thus, typically, the CSL drivers would be disposed apart from the first edge of the memory cell array region 10a by a protrusion length of the protrusion portions 11. In this case, spatial inefficiency is incurred due to an empty space between the memory cell array region 10a and the CSL drivers, and the spatial inefficiency is a factor that increases the chip manufacturing costs.

In one embodiment, therefore, the CSL drivers of the column decoder 20a have the same electrical characteristics while the CSL drivers have different layouts. For example, the column decoder 20a may include first CSL drivers and second CSL drivers. The first CSL drivers and the second CSL drivers may have the same electrical characteristics and different layouts. For example, the first CSL drivers may be formed of transistors that are disposed adjacent to the first edge of the memory cell array region 10a and that are arranged in one direction along the column direction. The second CSL drivers may be formed of transistors that are disposed apart from the first edge of the memory cell array region 10a by at least the protrusion length of the protrusion portions 11, and that are arranged in the column and row directions. As a result, as illustrated in FIG. 2, the column decoder 20a may have grooved portions that correspond to the protrusion portions 11, so that the spatial inefficiency does not occur. The first CSL drivers and the second CSL drivers will be described in detail at a later time.

The protrusion portions 11 may have circuits so as to control operations of sub-wordline drivers SWD that are disposed adjacent to the protrusion portions 11. For example, each protrusion portion 11 may have a control circuit that generates a signal (e.g., a PXID signal) to control a driving voltage (e.g., VPP) of the sub-wordline driver SWD.

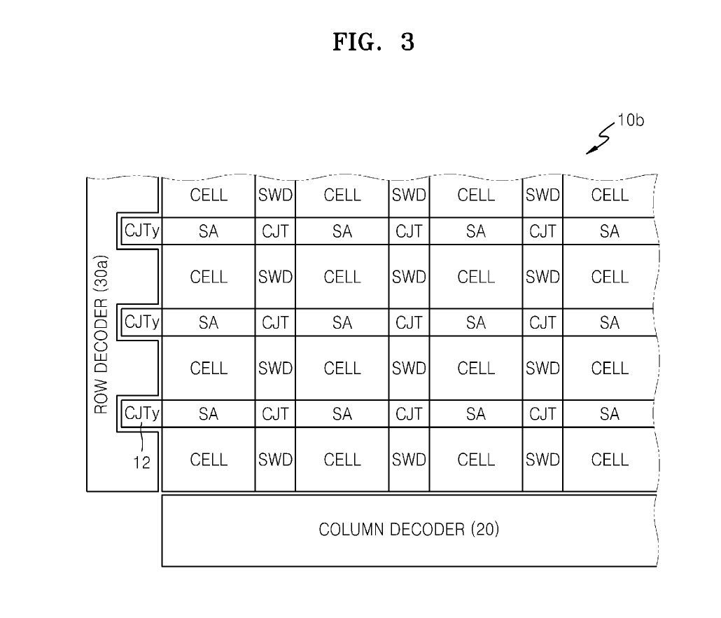

Referring to FIG. 3, the semiconductor memory device 100 may include the memory cell array region 10b and protrusion portions 12 that protrude from a second edge of the memory cell array region 10b. As a result, the protrusion portions protrude toward a row decoder 30a. Each protrusion portion 12 may be substantially the same as each conjunction region CJT between sense amplifiers SA, and hereinafter, may be referred to as ‘second protrusion conjunction region CJTy.’

The wordline drivers that are arranged in the column direction in the row decoder 30a generally have the same layout so as to ensure electrical characteristics that are equal to each other. However, in a case where a width of the wordline drivers in the column direction is greater than a pitch of the memory cells MC in the column direction, not all n wordline drivers can be disposed between the protrusion portions 12. In this case, the wordline drivers would be disposed apart from the second edge of the memory cell array region 10b by a protrusion length of the protrusion portions 12. In this case, spatial inefficiency is incurred due to an empty space between the memory cell array region 10b and the wordline drivers, and the spatial inefficiency is a factor that increases the chip manufacturing costs.

Therefore, in one embodiment, the wordline drivers of the row decoder 30a may have the same electrical characteristics while the wordline drivers have different layouts. For example, the row decoder 30a may include first wordline drivers and second wordline drivers. The first wordline drivers and the second wordline drivers may have the same electrical characteristics and different layouts. For example, the first wordline drivers may be formed of transistors that are disposed adjacent to the second edge of the memory cell array region 10b and that are arranged in one direction along the row direction. The second wordline drivers may be formed of transistors that are disposed apart from the second edge of the memory cell array region 10b by the protrusion length of the protrusion portions 12, and that are arranged in the column and row directions. As a result, as illustrated in FIG. 3, the row decoder 30a may have grooved portions that correspond to the protrusion portions 12, so that the spatial inefficiency does not occur.

The protrusion portions 12 may include circuits so as to control operations of the sense amplifiers SA that are adjacent to the protrusion portions 12. For example, the protrusion portions 12 may include circuits to provide a power voltage VDD to a PMOS sense amplifier and/or circuits to provide a ground voltage VDD to an NMOS sense amplifier.

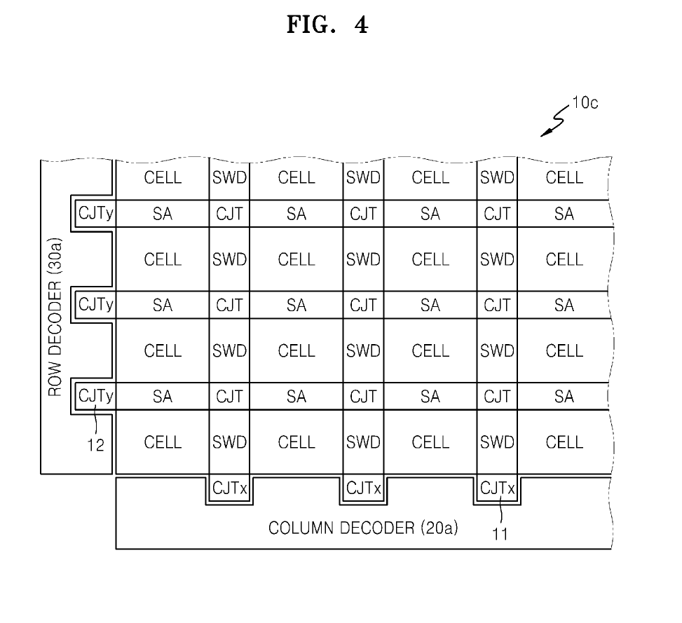

Referring to FIG. 4, the semiconductor memory device 100 may include the memory cell array region 10c, protrusion portions 11 that protrude from a first edge of the cell array region 10c, and protrusion portions 12 that protrude from a second edge of the cell array region 10c. As a result, the protrusion portions protrude toward a column decoder 20a and a row decoder 30a.

In one embodiment, as illustrated in FIG. 2, the column decoder 20a may include the CSL drivers that have the same electrical characteristics and different layouts. Also, as illustrated in FIG. 3, the row decoder 30a may include the wordline drivers that have the same electrical characteristics and different layouts. As a result, each of the column decoder 20a and the row decoder 30a may have grooved portions that correspond to the protrusion portions 11 and the protrusion portions 12. Thus, the column decoder 20a and the row decoder 30a may be disposed partly adjacent to the first and second edges, respectively, and partly adjacent to the protrusion portions, so that spatial inefficiency may be increased and the manufacturing costs may be decreased.

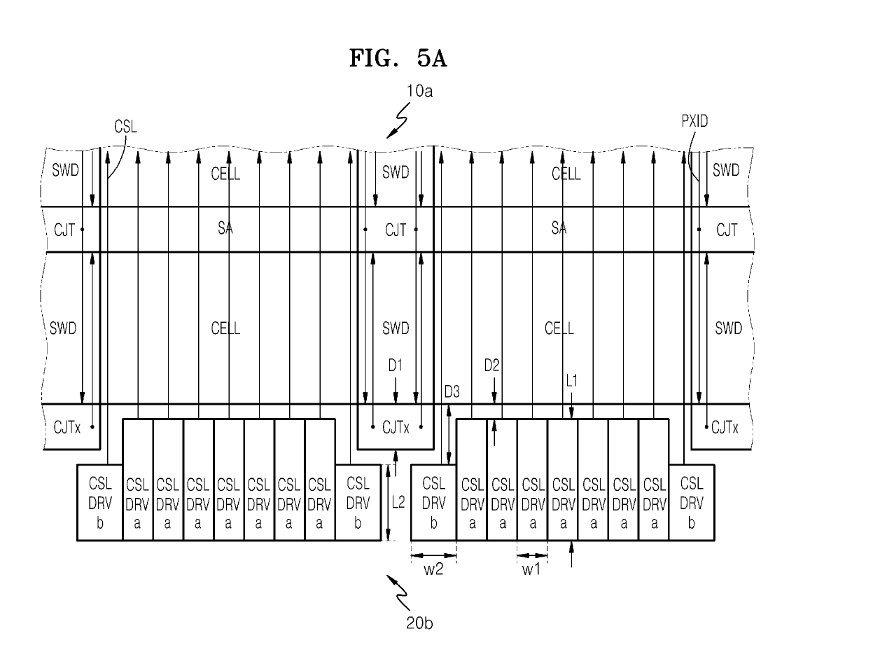

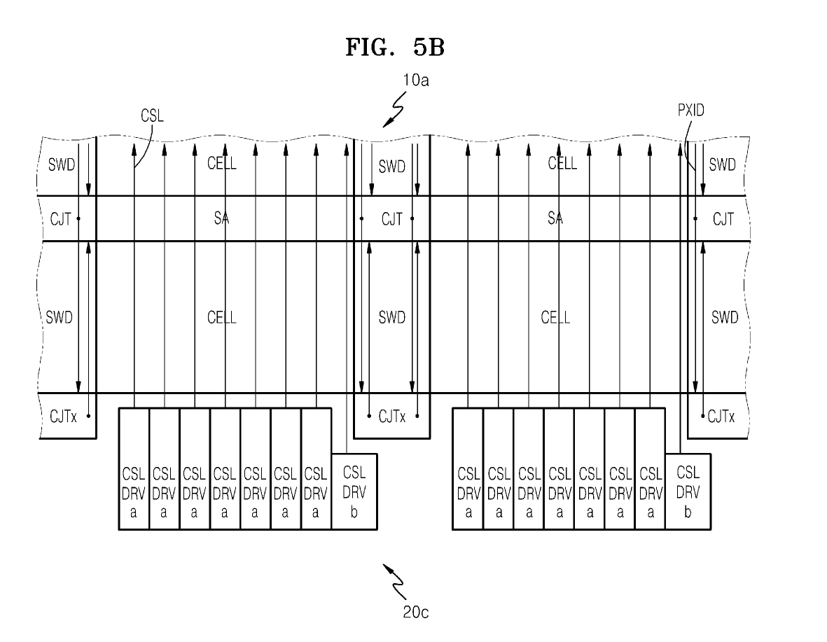

FIG. 5A is a partially magnified view of the memory cell array region 10a of FIGS. 2 and 4, and a column decoder 20b, according to an embodiment.

FIG. 5A illustrates the memory cell array region 10a, the protrusion portions CJTx, and the column decoder 20b. The memory cell array region 10a includes memory cell arrays CELL that are arranged in the row and column directions, sub-wordline drivers SWD that are disposed between memory cell arrays CELL in the row direction, sense amplifiers SA that are disposed between memory cell arrays CELL in the column direction, conjunction regions CJT that are disposed between sub-wordline drivers SWD in the column direction and sense amplifiers SA in the row direction. The first protrusion conjunction regions CJTx protrude from the first edge of the cell array region 10a.

The conjunction region CJT and the first protrusion conjunction region CJTx may include circuits so as to provide a control signal (e.g., a PXID signal) to provide a power voltage (e.g., VPP) to the sub-wordline drivers SWD that are disposed above and below the conjunction region CJT and the first protrusion conjunction region CJTx. As illustrated in FIG. 5A, the PXID signal is provided to the sub-wordline drivers SWD that are adjacent to the conjunction region CJT and the first protrusion conjunction region CJTx in the column direction. The first protrusion conjunction regions CJTx may include control circuits so as to control operations of the sub-wordline drivers SWD that are disposed above the first protrusion conjunction regions CJTx in FIG. 5A. As illustrated in FIG. 5A, the first protrusion conjunction regions CJTx may protrude from the first edge of the cell array region 10a by a first distance D1.

Column select lines CSL that extend in the column direction may be disposed on the memory cell arrays CELL and the sense amplifiers SA. As described above, a CSL signal is transferred via the column select line CSL, and controls a switch that connects a pair of bitlines and a pair of local I/O lines, so as to output a value of a memory cell to a local I/O line, wherein the memory cell is sensed and amplified by the sense amplifier SA. The CSL signal is driven by first and second CSL drivers CSL DRVa and CSL DRVb. As illustrated in FIG. 5A, the column decoder 20b including the first and second CSL drivers CSL DRVa and CSL DRVb is disposed adjacent to the first edge of the cell array region 10a. More specifically, the first drivers CSL DRVa may be disposed directly adjacent the memory cell array region 10a defined by the edges of the memory cell arrays CELL, and the second drivers CSL DRVb may be disposed directly adjacent an edge of the first protrusion conjunction regions CJTx parallel to the edge of the memory cell arrays CELL.

The first CSL drivers CSL DRVa and the second CSL drivers CSL DRVb may perform the same function and may have the same electrical characteristics. Thus, the first CSL drivers CSL DRVa and the second CSL drivers CSL DRVb may be formed of the same number of transistors, and in a circuit view, the first CSL drivers CSL DRVa and the second CSL drivers CSL DRVb may be the same. The transistors forming the first CSL drivers CSL DRVa, and the transistors forming the second CSL drivers CSL DRVb may correspond to each other and may have the same function and the same electrical characteristics. However, in one embodiment, the first CSL drivers CSL DRVa and the second CSL drivers CSL DRVb have different layouts. As illustrated in FIG. 5A, each first CSL driver CSL DRVa may be disposed in a region of a first length L1 in the column direction and a first width W1 in the row direction. On the other hand, each second CSL driver CSL DRVb may be disposed in a region of a second length L2 that is less than the first length L1 in the column direction and a second width W2 that is greater than the first width W1 in the row direction.

The first CSL drivers CSL DRVa may be arranged between the first protrusion conjunction regions CJTx in the row direction. Also, the second CSL drivers CSL DRVb may be disposed at both ends of the first CSL drivers CSL DRVa that are sequentially arranged in the row direction. The second CSL drivers CSL DRVb may be disposed adjacent to the first protrusion conjunction regions CJTx. Thus, the first CSL drivers CSL DRVa may include portions that are positioned at the same level as the first protrusion conjunction regions CJTx in the row direction, and the second CSL drivers CSL DRVb may not include portions that are positioned at the same level as the first protrusion conjunction regions CJTx in the row direction but may include portions that are positioned at the same level as the first protrusion conjunction regions CJTx in the column direction.

Also, the first CSL drivers CSL DRVa may be disposed apart from the first edge of the cell array region 10a by a second distance D2 that is less than the first distance D1. In one embodiment, the second CSL drivers CSL DRVb may be disposed apart from the first edge of the cell array region 10a by a third distance D3 that is greater than the first distance D1. Because the first CSL drivers CSL DRVa and the second CSL drivers CSL DRVb have the different layouts, an empty space between the memory cell array region 10a and the column decoder 20b may be minimized.

FIG. 5B is a partially magnified view of the memory cell array region 10a of FIGS. 2 and 4, and a column decoder 20c, according to another embodiment.

FIG. 5B illustrates the memory cell array region 10a, the protrusion portions CJTx, and the column decoder 20c. The memory cell array region 10a of FIG. 5B is substantially the same as the memory cell array region 10a of FIG. 5A. Also, the column decoder 20c of FIG. 5B is substantially the same as the column decoder 20b of FIG. 5A except that a second CSL driver CSL DRVb is only disposed at one end of first CSL drivers CSL DRVa that are sequentially arranged in the row direction. Because the memory cell array region 10a is described above with reference to FIG. 5A, detailed descriptions thereof are omitted here. Also, because the first and second CSL drivers CSL DRVa and CSL DRVb are described above with reference to FIG. 5A, detailed descriptions thereof are omitted here. Hereinafter, the embodiment of FIG. 5B will be described in consideration of a difference from the embodiment of FIG. 5A.

As illustrated in FIG. 5A, the second CSL drivers CSL DRVb may be disposed at both ends of the first CSL drivers CSL DRVa that are sequentially arranged in the row direction. On the other hand, as illustrated in FIG. 5B, the second CSL drivers CSL DRVb may be disposed at only first ends of the first CSL drivers CSL DRVa that are sequentially arranged in the row direction. In this manner, the column decoder 20c may be changed to various forms while the column decoder 20c minimizes an empty space with the memory cell array region 10.

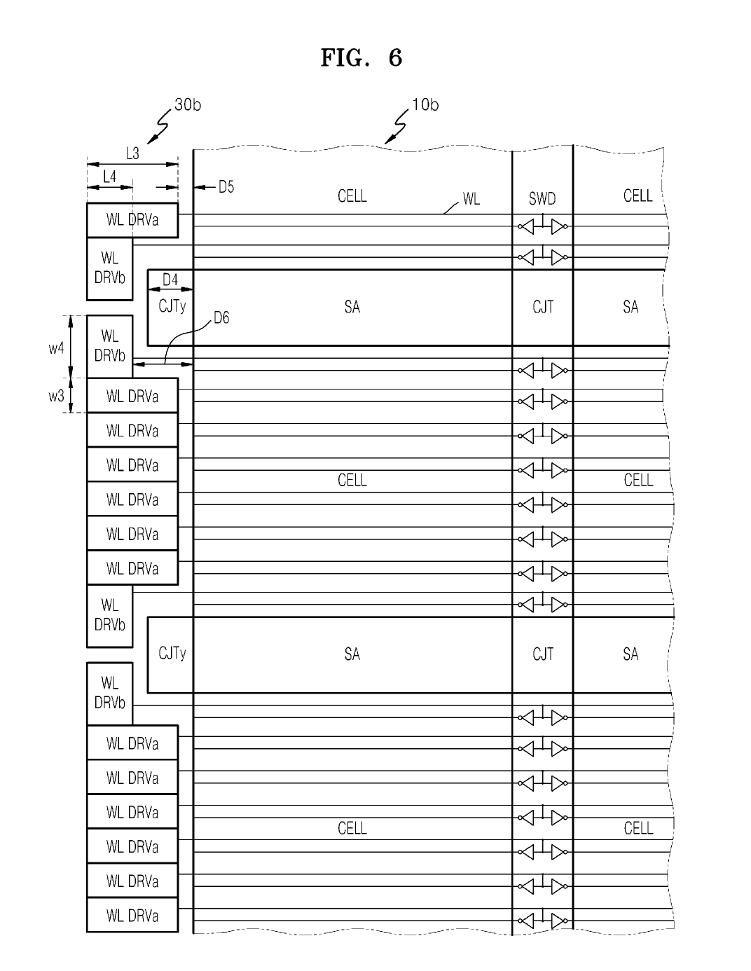

FIG. 6 is a partially magnified view of the memory cell array region 10b of FIGS. 3 and 4, and a row decoder 30b, according to an embodiment.

FIG. 6 illustrates the memory cell array region 10b, second protrusion conjunction regions CJTy, and the row decoder 30b. The memory cell array region 10b of FIG. 6 is substantially the same as the memory cell array region 10a of FIG. 5A except that second protrusion conjunction regions CJTy are illustrated in FIG. 6, instead of the first protrusion conjunction regions CJTx of FIG. 5A. The memory cell arrays CELL, the sense amplifiers SA, the sub-wordline drivers SWD, and the conjunction regions CJT in the memory cell array region 10b are described above with reference to FIG. 5A, and thus detailed descriptions thereof are omitted here.

Control circuits may be disposed in the conjunction region CJT and the second protrusion conjunction region CJTy so as to control operations of sense amplifiers SA that are disposed at both sides of the conjunction region CJT and the second protrusion conjunction region CJTy. For example, the control circuits may be disposed in the conjunction region CJT and the second protrusion conjunction region CJTy so as to provide a driving voltage to the sense amplifiers SA. A circuit to provide a power voltage VDD to a PMOS sense amplifier and/or a circuit to provide a ground voltage VDD to an NMOS sense amplifier may be disposed in each of the conjunction region CJT and the second protrusion conjunction region CJTy. Also, the conjunction region CJT may include a circuit so as to provide a control signal (e.g., a PXID signal) to provide a power voltage (e.g., VPP) to the sub-wordline drivers SWD that are disposed above and below the conjunction region CJT. As illustrated in FIG. 6, the second protrusion conjunction regions CJTy may protrude from the from the second edge of the cell array region 10b by a fourth distance D4.

In one embodiment, the row decoder 30b includes first and second wordline drivers WL DRVa and WL DRVb so as to drive the wordlines WL. As illustrated in FIG. 6, the row decoder 30b that includes the first and second wordline drivers WL DRVa and WL DRVb is disposed adjacent to the second edge of the cell array region 10b extending in the column direction. More specifically, the first wordline drivers WL DRVa may be disposed directly adjacent the memory cell array region 10a defined by the edges of the memory cell arrays CELL, and the second wordline drivers WL DRVb may be disposed directly adjacent an edge of the second protrusion conjunction regions CJTy parallel to the edge of the memory cell arrays CELL.

The first wordline drivers WL DRVa and the second wordline drivers WL DRVb may perform the same function and may have the same electrical characteristics. The first wordline drivers WL DRVa and the second wordline drivers WL DRVb may be formed of the same number of transistors. The transistors forming the first wordline drivers WL DRVa, and the transistors forming the second wordline drivers WL DRVb may correspond to each other and may have the same function and the same electrical characteristics. However, the first wordline drivers WL DRVa and the second wordline drivers WL DRVb may have different layouts. As illustrated in FIG. 6, each first wordline driver WL DRVa may be disposed in a region of a third length L3 in the row direction and a third width W3 in the column direction. Each second wordline driver WL DRVb may be disposed in a region of a fourth length L4 that is less than the third length L3 in the row direction and a fourth width W4 that is greater than the third width W3 in the column direction.

The first wordline drivers WL DRVa may be arranged between the second protrusion conjunction regions CJTy in the column direction. Also, the second wordline drivers WL DRVb may be disposed at both ends of the first wordline drivers WL DRVa that are sequentially arranged in the column direction. The second wordline drivers WL DRVb may be disposed adjacent to the second protrusion conjunction region CJTy. Thus, the first wordline drivers WL DRVa may include portions that are positioned at the same level as the second protrusion conjunction region CJTy in the column direction, and the second wordline drivers WL DRVb may not include portions that are positioned at the same level as the second protrusion conjunction region CJTy in the column direction but may include portions that are positioned at the same level as the second protrusion conjunction region CJTy in the row direction.

Also, the first wordline drivers WL DRVa may be disposed apart from the second edge of the cell array region 10b by a fifth distance D5 that is less than the fourth distance D4. The second wordline drivers WL DRVb may be disposed apart from the second edge of the cell array region 10b by a sixth distance D6 that is greater than the fourth distance D4. Because the first wordline drivers WL DRVa and the second wordline drivers WL DRVb have the different layouts, an empty space between the memory cell array region 10b and the row decoder 30b may be minimized.

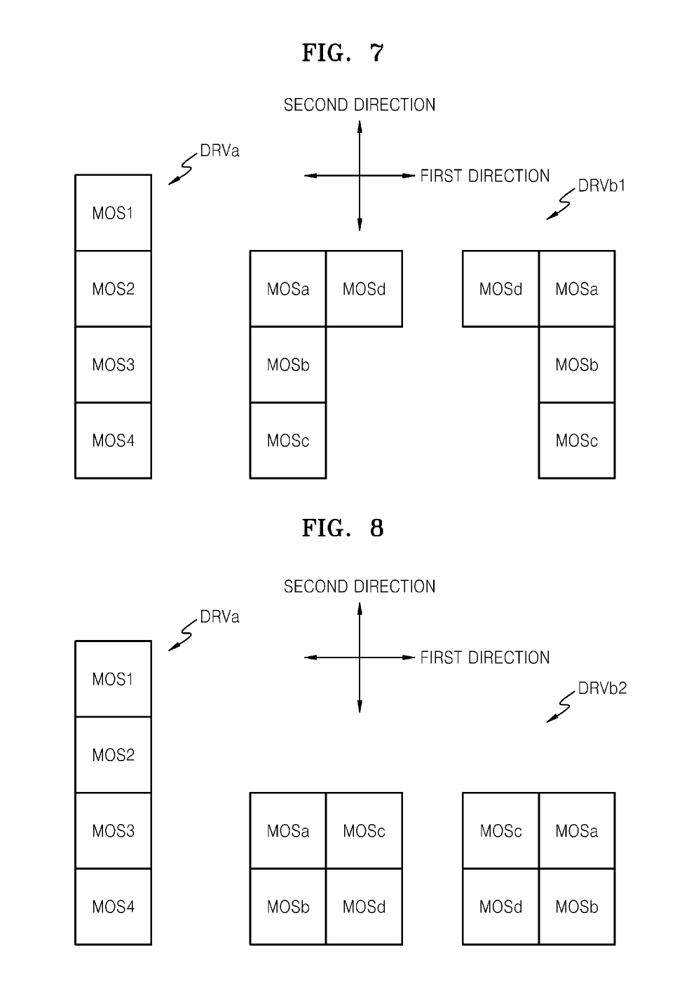

FIGS. 7 through 11 illustrate layouts of first and second drivers of FIGS. 5A and 6, according to various exemplary embodiments. The first and second drivers illustrated in FIGS. 7 through 11 may be the first and second wordline drivers WL DRVa and WL DRVb illustrated in FIG. 5A or may be the first and second wordline drivers WL DRVa and WL DRVb illustrated in FIG. 6. Also, it is assumed that each of the first and second drivers is formed of four transistors, e.g., MOS transistors.

FIG. 7 illustrates a first driver DRVa and a pair of second drivers DRVb1. The first driver DRVa is formed of first through fourth transistors MOS1 through MOS4 that are arranged in one direction in a second direction. The second driver DRVb1 is formed of first through fourth transistors MOSa through MOSd that are arranged in first and second directions. For example, the second driver DRVb1 may be formed of the three transistors MOSa through MOSc that are arranged in the second direction, and the fourth transistor MOSd that is adjacent to the first transistor MOSa in the first direction. Thus, the second driver DRVb1 may have a greater width than the first driver DRVa in the first direction, and a lesser length than the first driver DRVa in the second direction. Accordingly, a protrusion portion of a memory cell array region may be disposed above the pair of second drivers DRVb1, so that spatial efficiency may be increased.

As illustrated in FIG. 7, the first driver DRVa and the second driver DRVb1 may have different layouts but may have the same function and electrical characteristics. Also, the first through fourth transistors MOS1 through MOS4 of the first driver DRVa may correspond to the first through fourth transistors MOSa through MOSd of the second driver DRVb1, respectively. For example, the first through fourth transistors MOS1 through MOS4 may correspond to the first through fourth transistors MOSa through MOSd, respectively but one or more embodiments of the inventive concept are not limited thereto. For example, the first transistor MOS1 may correspond to the fourth transistor MOSd, and the second through fourth transistors MOS2 through MOS4 may correspond to the first through third transistors MOSa through MOSc, respectively.

Also, although FIG. 7 illustrates an example in which sizes of the first through fourth transistors MOS1 through MOS4 and MOSa through MOSd are equal, one or more embodiments are not limited thereto. For example, the first and second transistors MOS1 and MOS2 may have greater sizes or greater lengths in the second direction, compared to the third and fourth transistors MOS3 and MOS4.

FIG. 8 illustrates a first driver DRVa and a pair of second drivers DRVb2, according to another embodiment.

The first driver DRVa is formed of first through fourth transistors MOS1 through MOS4 that are arranged in one direction in a second direction. The second driver DRVb2 is formed of first and second transistors MOSa and MOSb that are arranged in the second direction, and third and fourth transistors MOSc and MOSd that are adjacent to the first and second transistors MOSa and MOSb in a first direction. Thus, the second driver DRVb2 may have a greater width than the first driver DRVa in the first direction, and a lesser length than the first driver DRVa in the second direction. As illustrated in FIG. 8, the first driver DRVa and the second driver DRVb2 may have different layouts but may have the same function and electrical characteristics. In the embodiment of FIG. 8, the first and fourth transistors MOS1 and MOS4 may correspond to the third and fourth transistors MOSc and MOSd, respectively, and the second and third transistors MOS2 and MOS3 may correspond to the first and second transistors MOSa and MOSb, respectively.

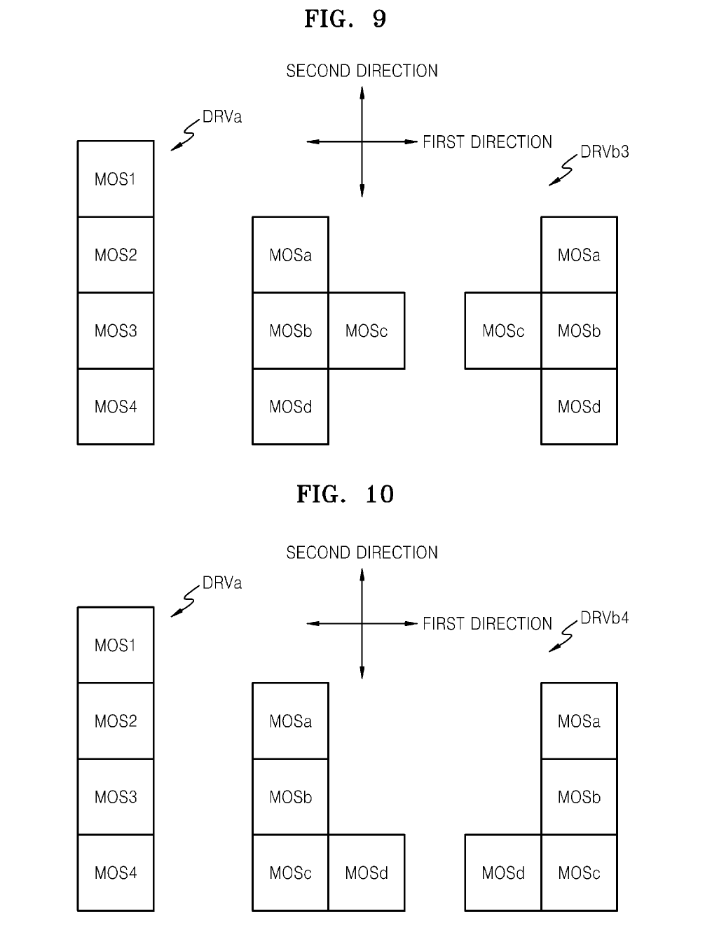

Referring to FIGS. 9 and 10, a first driver DRVa and a pair of second drivers DRVb3 are illustrated in FIG. 9, and a first driver DRVa and a pair of second drivers DRVb4 are illustrated in FIG. 10, according to another embodiment. The first driver DRVa is formed of first through fourth transistors MOS1 through MOS4 that are arranged in one direction in a second direction. The second driver DRVb3 illustrated in FIG. 9 may be formed of first, second, and fourth transistors MOSa, MOSb, and MOSd that are arranged in the second direction, and a third transistor MOSc that is adjacent to the second transistor MOSb in a first direction. Also, the second driver DRVb4 of FIG. 10 may be formed of first through third transistors MOSa through MOSc that are arranged in a second direction, and a fourth transistor MOSd that is adjacent to the third transistor MOSc in a first direction.

Thus, compared to the first driver DRVa, the second driver DRVb3 and the second driver DRVb4 may have greater widths in the first direction and lesser lengths in the second direction. As illustrated in FIGS. 9 and 10, the first driver DRVa, and the second drivers DRVb3 and DRVb4 may have different layouts but may have the same function and electrical characteristics. In the embodiment of FIG. 9, the first, second, and fourth transistors MOS1, MOS2, and MOS4 may correspond to the first, second, and fourth transistors MOSa, MOSb, and MOSd, respectively, and the third transistor MOS3 may correspond to the third transistors MOSc. Also, in the embodiment of FIG. 10, the first through fourth transistors MOS1 through MOS4 may correspond to the first through fourth transistors MOSa through MOSd, respectively.

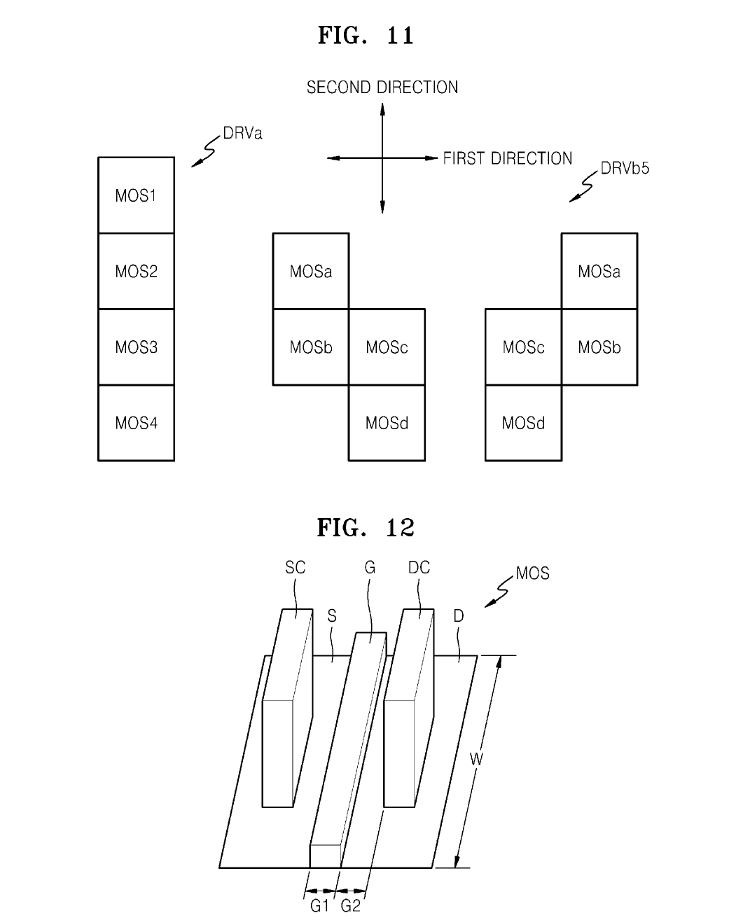

FIG. 11 illustrates a first driver DRVa and a pair of second drivers DRVb5, according to another embodiment. The first driver DRVa may be formed of first through fourth transistors MOS1 through MOS4 that are arranged in one direction in a second direction. The second driver DRVb5 may be formed of first and second transistors MOSa and MOSb, and third and fourth transistors MOSc and MOSd, which are arranged in the second direction, and the second and third transistors MOSb and MOSc may be arranged in a first direction. Thus, as illustrated in FIG. 11, the second driver DRVb5 may have a greater width in the first direction, and a lesser length in the second direction, compared to the first driver DRVa. The first driver DRVa and the second driver DRVb5 may have different layouts but may have the same function and electrical characteristics. In the embodiment of FIG. 11, the first through fourth transistors MOS1 through MOS4 may correspond to the first through fourth transistors MOSa through MOSd, respectively.

However, corresponding relations between the transistors MOS1 through MOS4, and MOSa through MOSd, which are described above with reference to FIGS. 7 through 11, may vary in one or more of the disclosed embodiments. Also, when the first driver DRVa and the pairs of the second drivers DRVb1 through DRVb5 are first and second CSL drivers, the first direction indicates the row direction, and the second direction indicates the column direction. Also, when the first driver DRVa and the pairs of the second drivers DRVb1 through DRVb5 are first and second wordline drivers, the first direction indicates the column direction, and the second direction indicates the row direction. Hereinafter, the second drivers DRVb1 through DRVb5 may be collectively referred to as ‘second driver DRVb.’

FIG. 12 schematically illustrates an exemplary structure of the transistors shown in FIGS. 7 through 11 according to an embodiment.

FIG. 12 illustrates a MOS transistor MOS including a gate electrode G that is formed on an active region, a source region S and a drain region D which are defined by the gate electrode G, and a source via contact SC and a drain via contact DC which are connected to the source region S and the drain region D, respectively. Although not illustrated in FIG. 12, a gate insulating layer is disposed between the active region Act and the gate electrode G. Also, the gate electrode G has a width of a first distance G1, and the width corresponds to a channel length of the MOS transistor MOS. In addition, the gate electrode G is separated from the source via contact SC and the drain via contact DC by a second distance G2.

According to one or more embodiments, the first driver DRVa and the second driver DRVb may have different layouts but may have the same function and electrical characteristics. For this, the transistors forming the first driver DRVa correspond to the transistors forming the second driver DRVb, respectively. According to the one or more embodiments, the transistors that correspond to each other have gate electrodes having the same width. For example, when the first transistor MOS1 and the fourth transistor MOSd of FIG. 7 correspond to each other, a width of a gate electrode of the first transistor MOS 1 is equal to a width of a gate electrode of the fourth transistor MOSd.

Also, according to one or more embodiments, the transistors that correspond to each other have the same distance between the gate electrode G and each of the source via contact SC and the drain via contact DC. For example, in a case where the first transistor MOS1 and the fourth transistor MOSd of FIG. 7 correspond to each other, when a distance between the gate electrode G and each of the source via contact SC and the drain via contact DC is a second distance G2 in the first transistor MOS1, a distance between the gate electrode G and each of the source via contact SC and the drain via contact DC is also a second distance G2 in the fourth transistor MOSd.

In this embodiment, a width of a gate electrode and/or a distance between the gate electrode and each of via contacts of a transistor in the first driver DRVa are designed to be equal to those of a transistor in the second driver DRVb, so that it is possible to ensure that the first driver DRVa and the second driver DRVb have the same electrical characteristics. Thus, the first driver DRVa and the second driver DRVb may be designed to have different layouts but still have the same electrical characteristics.

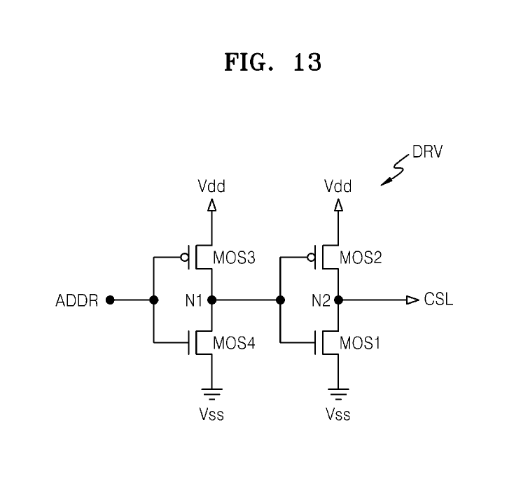

FIG. 13 is a circuit diagram of a driver DRV from among the drivers shown in FIGS. 7 through 11, according to an embodiment.

Referring to FIG. 13, the driver DRV may be formed of four MOS transistors MOS1 through MOS4. The driver DRV may be a CSL driver. Hereinafter, it is assumed that the driver DRV is the CSL driver.

The first transistor MOS1 may be an NMOS transistor and may have a source connected to a ground voltage VSS, a drain connected to a second node N2, and a gate connected to a first node N1. The second transistor MOS2 may be a PMOS transistor and may have a drain connected to a power voltage VDD, a source connected to the second node N2, and a gate connected to the first node N1. The third transistor MOS3 may be a PMOS transistor and may have a drain connected to a power voltage VDD, a source connected to the first node N1, and a gate to which a decoded address signal ADDR is input. The fourth transistor MOS4 may be an NMOS transistor and may have a source connected to a ground voltage VSS, a drain connected to the first node N1, and a gate to which the decoded address signal ADDR is input. The second node N2 may be connected to a column select line CSL and may output a CSL signal. As described above, in order to drive the column select line CSL, the first and second transistors MOS1 and MOS2 may have current driving capacity greater than that of the third and fourth transistors MOS3 and MOS4.

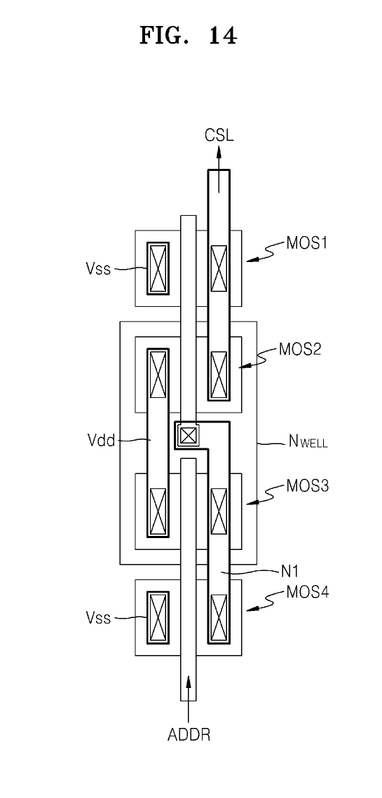

FIG. 14 illustrates a layout diagram of a first CSL driver in the circuit diagram of FIG. 13, according to an embodiment.

Referring to FIG. 14, first through fourth transistors MOS1 through MOS4 are arranged in one direction. Also, an N-type well N well is disposed to form the second and third transistors MOS2 and MOS3 that are PMOS transistors. Sources and drains of the first through fourth transistors MOS1 through MOS4 are connected to a column select line CSL, a power voltage VDD, a ground voltage VSS, or a first node N1 by via contacts. A decoded address signal ADDR is provided to gates of the third and fourth transistors MOS3 and MOS4.

Referring to FIG. 14, sizes of the first through fourth transistors MOS1 through MOS4 are equal to each other. However, in order to allow the first and second transistors MOS1 and MOS2 to have greater current driving capacity, a channel width of the first and second transistors MOS1 and MOS2 may be greater than a channel width of the third and fourth transistors MOS3 and MOS4. Although not illustrated in FIG. 14, the first and fourth transistors MOS 1 and MOS4 may be NMOS transistors and may be formed on a P-type substrate (not shown).

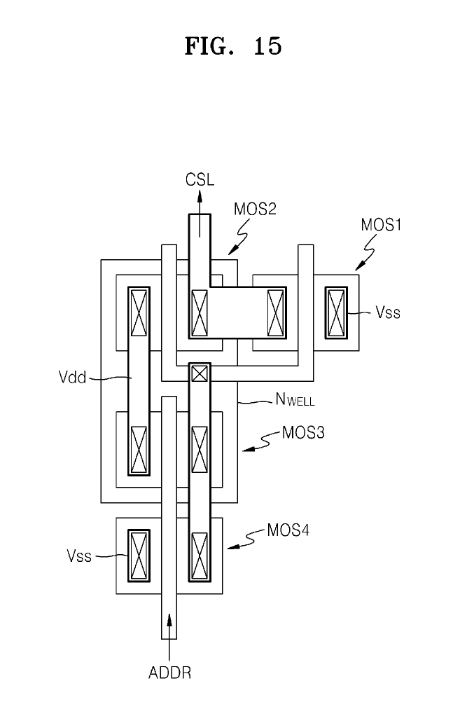

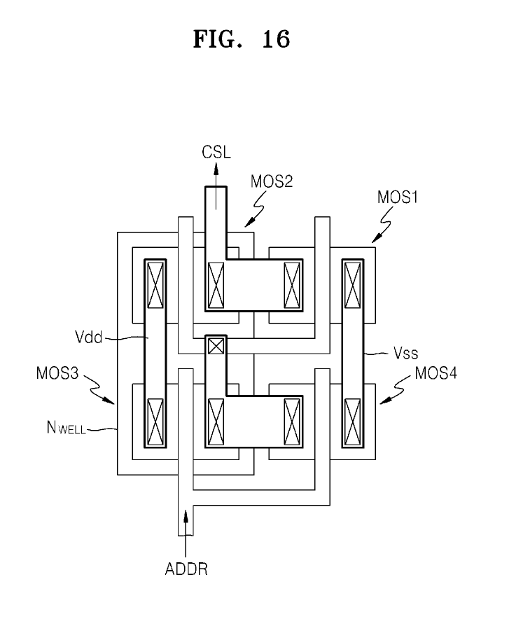

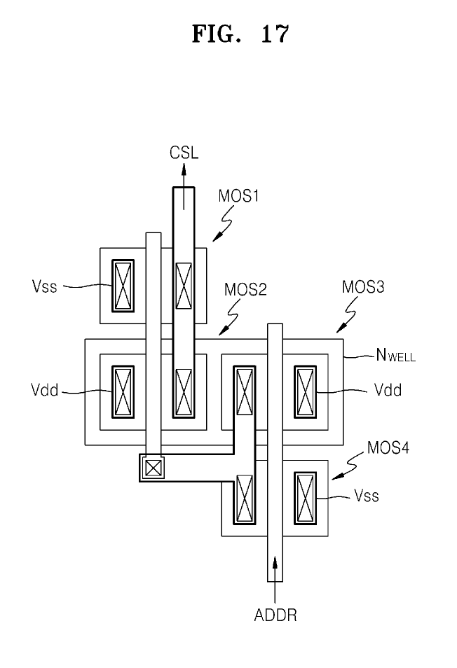

FIGS. 15 through 17 illustrate layout diagrams of a second CSL driver in the circuit diagram of FIG. 13, according to embodiments. FIG. 15 illustrates a layout diagram of the second driver DRVb1 of FIG. 7, FIG. 16 illustrates a layout diagram of the second driver DRVb2 of FIG. 8, and FIG. 17 illustrates a layout diagram of the second driver DRVb5 of FIG. 11 according to an embodiment.

Referring to FIG. 15, second and fourth transistors MOS2 through MOS4 may be vertically arranged in one direction, and a first transistor MOS1 may be disposed adjacent to the second transistors MOS2 in a horizontal direction. As a result, compared to the layout of the first CSL driver shown in FIG. 14, the layout of the second CSL driver shown in FIG. 15 has a greater length in the horizontal direction and a lesser length in a vertical direction. Thus, a protrusion portion of a memory cell array region may be disposed in an upper portion of the second CSL driver shown in FIG. 15.

Also, compared to the layout of the first CSL driver shown in FIG. 14, although the first transistor MOS1 has moved adjacent to the second transistor MOS2, as illustrated in FIGS. 14 and 15, a channel length and/or a distance between a gate electrode and a via contact in the first transistor MOS1 may be constantly maintained. Thus, it is possible to ensure that the first CSL driver shown in FIG. 14, and the second CSL driver shown in FIG. 15 have the same electrical characteristics.

Referring to FIG. 16, second and third transistors MOS2 and MOS3 may be arranged in a vertical direction, a first transistor MOS1 may be disposed in a right side of the second transistor MOS2 in a horizontal direction, and a fourth transistor MOS4 may be disposed in a right side of the third transistor MOS3 in the horizontal direction. As a result, compared to the layout of the first CSL driver shown in FIG. 14, the layout of the second CSL driver shown in FIG. 16 has a greater length in the horizontal direction and a lesser length in a vertical direction. Thus, a protrusion portion of a memory cell array region may be disposed in an upper portion of the second CSL driver shown in FIG. 16.

Also, compared to the layout of the first CSL driver shown in FIG. 14, although the first transistor MOS1 and the fourth transistor MOS4 have moved to the right sides of the second transistor MOS2 and the third transistor MOS3, respectively, as illustrated in FIGS. 14 and 16, a channel length and/or a distance between a gate electrode and a via contact in each of the first transistor MOS1 and the fourth transistor MOS4 may be constantly maintained. Thus, it is possible to ensure that the first CSL driver shown in FIG. 14, and the second CSL driver shown in FIG. 16 have the same electrical characteristics.

Referring to FIG. 17, first and second transistors MOS1 and MOS2 may be arranged in a vertical direction, and third and fourth transistors MOS3 and MOS4 may be arranged in the vertical direction in a right side of the first and second transistors MOS1 and MOS2. As illustrated in FIG. 17, the third transistor MOS3 may be disposed in the right side of the second transistor MOS2. As a result, compared to the layout of the first CSL driver shown in FIG. 14, the layout of the second CSL driver shown in FIG. 17 has a greater length in the horizontal direction and a lesser length in a vertical direction. Thus, a protrusion portion of a memory cell array region may be disposed in an upper portion of the second CSL driver shown in FIG. 17.

Also, compared to the layout of the first CSL driver shown in FIG. 14, although the third and fourth transistors MOS3 and MOS4 have moved to the right side of the second transistor MOS2, and an N-type well N well is formed while extending in a horizontal direction, as illustrated in FIGS. 14 and 17, a channel length and/or a distance between a gate electrode and a via contact in each of the third and fourth transistors MOS3 and MOS4 may be constantly maintained. Thus, it is possible to ensure that the first CSL driver shown in FIG. 14, and the second CSL driver shown in FIG. 17 have the same electrical characteristics.

The row decoder and/or the column decoder of the semiconductor memory device according to the one or more embodiments may include the first driver having the layout shown in FIG. 14, and the second driver having one of the layouts shown in FIGS. 15 through 17. Thus, although the protrusion portion has a layout that protrudes toward the row decoder and/or the column decoder, the row decoder and/or the column decoder has the second driver having a short length so as to correspond to the protruding portion, so that an empty space between the memory cell array region and the row decoder and/or the column decoder may be minimized. Accordingly, spatial efficiency may be increased, and the manufacturing costs may be reduced.

While the disclosure has been particularly shown and described with reference to exemplary embodiments thereof, it will be understood that various changes in form and details may be made therein without departing from the spirit and scope of the following claims.

What is claimed is:

1. A semiconductor memory device comprising:
a memory cell array region comprising a plurality of memory cell arrays each array including memory cells that are arranged in row and column directions, sub-wordline drivers that are disposed between memory cell arrays in the row direction, and conjunction regions that are disposed between sub-wordline drivers in the column direction;
protrusion conjunction regions that are disposed adjacent to a first group of the sub-wordline drivers positioned at a first edge of the memory cell array region extending in the row direction and that protrude from the first edge in the column direction; and
a column decoder comprising first column select line (CSL) drivers each having a first physical layout and second CSL drivers each having a second physical layout different from the first physical layout, the first and second CSL drivers being disposed adjacent to the first edge of the memory cell array region,
wherein the number of the first CSL drivers is greater than the number of the second CSL drivers.

2. The semiconductor memory device of claim 1, wherein the protrusion conjunction regions protrude from the first edge of the memory cell array region by a first distance,
wherein each of the first CSL drivers is disposed apart from the first edge by a second distance less than the first distance, and
wherein each of the second CSL drivers is disposed apart from the first edge by a third distance greater than the first distance.

3. The semiconductor memory device of claim 1, wherein the first CSL driver is formed of transistors that are arranged in the column direction, and the second CSL driver comprises at least two transistors that are arranged in the row direction.

4. A semiconductor memory device comprising:
a memory cell array region comprising a plurality of memory cell arrays arranged in row and column directions;
a protrusion portion protruding from at least one edge of the memory cell array region in at least one of the row and column directions;
sub-wordline drivers disposed between memory cell arrays in the row direction, and configured to generate word line signals in response to driver signals;
a row decoder including first drivers and second drivers, the row decoder disposed adjacent to a first edge of the memory cell array region extending in the column direction, and configured to generate the driver signals; and
a column decoder including third drivers and fourth drivers, the column decoder disposed adjacent to a second edge perpendicular to the first edge of the memory cell array region extending in the row direction, and configured to generate column select line (CSL) signals,
wherein at least one of the first drivers includes a physical layout different from at least one of the second drivers, or at least one of the third drivers includes a physical layout different from at least one of the fourth drivers.

5. The semiconductor memory device of claim 4, wherein each of the first drivers is disposed apart from the first edge by a first distance and each of the second drivers is disposed apart from the first edge by a second distance greater than the first distance.

6. The semiconductor memory device of claim 4, wherein each of the third drivers is disposed apart from the second edge by a first distance and each of the fourth drivers is disposed apart from the second edge by a second distance greater than the first distance.

7. The semiconductor memory device of claim 4, wherein, when the protrusion portion protrudes from the first edge in the row direction, the first driver comprises a portion that is positioned at the same level as the protrusion portion in the column direction, and the second driver comprises a portion that is positioned at the same level as the protrusion portion in the row direction and does not comprise a portion that is positioned at the same level as the protrusion portion in the column direction.

8. The semiconductor memory device of claim 4, wherein each of the first drivers has a first layout, and each of the second drivers has a second layout, and
wherein a length of the first layout in a first direction is greater than a length of the second layout in the first direction, and a width of the first layout in a second direction perpendicular to the first direction is less than a width of the second layout in the second direction.

9. The semiconductor memory device of claim 4, wherein each of the third drivers has a first layout, and each of the second drivers has a second layout, and
wherein a length of the first layout in a first direction is greater than a length of the second layout in the first direction, and a width of the first layout in a second direction perpendicular to the first direction is less than a width of the second layout in the second direction.

10. The semiconductor memory device of claim 4, wherein each of the first drivers is formed of first transistors, each of the second drivers is formed of second transistors, and the first transistors and the second transistors correspond to each other, respectively, and
wherein the first transistors and the second transistors that correspond to each other have the same channel length.

11. The semiconductor memory device of claim 10, wherein each of the first and second transistors comprises impurity regions, a gate electrode crossing between the impurity regions, and via contacts respectively connected to the impurity regions, and
wherein the first transistors and the second transistors that correspond to each other have the same distance between the gate electrode and the via contacts.

12. The semiconductor memory device of claim 4, wherein each of the third drivers is formed of first transistors, each of the second drivers is formed of second transistors, and the first transistors and the second transistors correspond to each other, respectively, and
wherein the first transistors and the second transistors that correspond to each other have the same channel length.

13. The semiconductor memory device of claim 4, wherein the memory cell array region further comprises sub-wordline drivers that are disposed between memory cell arrays in the row direction, sense amplifiers that are disposed between memory cell arrays in the column direction, and conjunction regions that are disposed between sense amplifiers in the row direction and that are disposed between sub-wordline drivers in the column direction, and
wherein the protrusion portion comprises first protrusion conjunction regions that are adjacent to a first group of the sub-wordline drivers in the column direction, wherein the first group of the sub-wordline drivers are disposed at the second edge of the memory cell array region extending in the row direction, or comprises second protrusion conjunction regions that are adjacent to a first group of the sense amplifiers in the row direction, wherein the first group of the sense amplifiers are disposed at the first edge of the memory cell array region extending in the column direction.

14. The semiconductor memory device of claim 13, wherein the first protrusion conjunction regions include circuits configured to control operations of the sub-wordline drivers adjacent to the first protrusion conjunction regions in the column direction.

15. The semiconductor memory device of claim 13, wherein the second protrusion conjunction regions include circuits configured to control operations of the sense amplifiers adjacent to the second protrusion conjunction regions in the row direction.

16. A semiconductor memory device comprising:
a memory cell array region including a plurality of memory cell arrays arranged in row and column directions;
a column decoder including a plurality of column select line (CSL) drivers disposed adjacent to a first edge of the memory cell array region extending in the row direction, and configured to generate a plurality of column select line signals; and
a row decoder including a plurality of main word line (MWL) drivers disposed adjacent to a second edge of the memory cell array region extending in the column direction, and configured to generate a plurality of main word line signals,
wherein the CSL drivers includes first and second CSL drivers, each of the first CSL drivers including a physical layout different from each of the second CSL drivers, and
wherein a number of the first CSL drivers is greater than a number of the second CSL drivers.

17. The device of claim 16, further comprising:
a plurality of sub-wordline drivers disposed between memory cell arrays in the row direction;
a plurality of sense amplifiers disposed between memory cell arrays in the column direction; and
a plurality of control circuits disposed between sub-wordline drivers in the column direction and between sense amplifiers in the row direction, and configured to generate first control signals coupled to the sub-wordline drivers or second control signals coupled to the sense amplifiers.

18. The device of claim 16, wherein each of the first CSL drivers is disposed apart from the first edge of the memory cell array region by a first distance, and
wherein each of the second CSL drivers is disposed apart from the first edge by a second distance greater than the first distance.

19. The device of claim 16, wherein the MWL drivers include first and second MWL drivers, each of the first MWL drivers including a physical layout different from each of the second MWL drivers, and
wherein the number of the first MWL drivers is greater than the number of the second MWL drivers.

20. The device of claim 19, each of the first MWL drivers is disposed apart from the second edge of the memory cell array region by a first distance, and
wherein each of the second MWL drivers is disposed apart from the second edge by a second distance greater than the first distance.
